(19) United States
(12) Patent Application Publication
(10) Pub. No.: US 2024/0369513 A1
(43) Pub. Date: Nov. 7, 2024

(54) METHOD FOR DISCRIMINANT MONITORING OF A COMPOSITE MULTI-MATERIAL ASSEMBLY

(71) Applicant: EPSILON COMPOSITE, GAILLAN EN MEDOC (FR)

(72) Inventor: Denis FERRER, VERTHEUIL (FR)

(21) Appl. No.: 18/556,659

(22) PCT Filed: Apr. 28, 2022
(86) PCT No.: PCT/FR2022/050810

§ 371 Date: Oct. 20, 2023

(30) Foreign Application Priority Data
Apr. 29, 2021 (FR) FR2104512

(51) Int. Cl. G01N 27/92

(52) U.S. Cl. CPC G01N 27/92

(57) ABSTRACT

The invention relates to a method for the discriminant monitoring of a composite multi-material assembly comprising at least one internal layer made of a first, electrically conductive composite material and a second layer made of a second, electrically insulating composite material, the second layer covering the first internal layer. The method comprises the following steps: preparing the composite multi-material assembly by exposing a portion of the internal layer constituting a first electrode; applying a second electrode to the surface of the second layer, earthing one of these electrodes; discriminant monitoring by means of generating a current between the first electrode and second electrode by applying a threshold voltage U_{S} pre-defined by calibration to be characteristic of a lack of structural defects, the appearance of a breakdown at a voltage lower than said threshold voltage U_{S} indicative of the presence of at least one structural defect in the composite assembly.

### TECHNICAL FIELD OF THE INVENTION

The present invention relates to the field of composite multi-material assemblies comprising two joined layers, the internal one of which is made of an electrically conductive material and the other, external one of which is made of an electrically insulating material.

In particular, the present invention relates to the field of civil engineering infrastructures linked to the transport of energy, and more specifically to the field of overhead powerlines, on which it is sought to perform discriminant monitoring with a view to detecting, or even locating, a defect in the external layer made of insulating material and/or in the internal layer propagating under storage stress through the external layer.

For the purposes of the present invention, composite means a material comprising reinforcing fibers of great length and a matrix impregnating the reinforcing fibers to constitute the various layers of the composite.

For the purposes of the present invention, a composite multi-material assembly refers to a composite consisting of two types of reinforcing fiber, in particular carbon fibers (forming the internal layer) and glass fibers (forming the external layer or second layer) impregnated in the same resin guaranteeing a cohesive interface between the two layers.

### TECHNICAL BACKGROUND

The need for cables for transport and electrical distribution is increasing with ever-increasing demand for electricity. In order to not only meet this need for increase, but also to improve the capacity of existing cables and also to improve their mechanical performance, there are currently composite multi-material assemblies with a composite structural core mainly consisting of a composite core based on carbon fibers and of a structural and insulating layer made of composite based on glass fibers (also called rods). These assemblies, which have been developed by the applicant, are typically obtained by implementing a process for manufacturing by pultrusion from a bundle of carbon fibers and a polymer matrix impregnating and bonding the carbon fibers to obtain the composite core based on carbon fibers, while the structural and insulating layer is obtained during the same pultrusion operation from a bundle of glass fibers and the same polymer matrix to impregnate and bind the glass fibers.

The manufacturing process of such assemblies intrinsically comprises major risks of:
a defect during the implementation of the pultrusion manufacturing process (non-aligned fibers, fibers jamming or breaking, poor impregnation, rods cracking due to thermal firing stresses, etc.) can cause the mechanical properties of the assembly to decline, and thus not meet the minimum mechanical and thermal performance criteria during quality controls;
the risks of impacts during the manufacture and packaging of assemblies also represent a significant risk, which is difficult to control with a major impact on the residual mechanical performance of the composite rods.
in addition, once wound onto rotating devices of the reel or roll type, then packaged for their transport, these rods then pass typically several weeks in a restrictive environment, in particular in the case of maritime transport because of high moisture and temperatures that can be extreme (either very high, or very low), and unmonitored storage conditions on the destination site.

Due to the position of the structural and insulating layer made from glass fiber-based composite in the rod relative to the composite core based on carbon fibers and on its rigidity lower than carbon, the first appearance of a fracture on the bending product will theoretically take place at the glass fiber-based insulating layer during external impacts generating a loss of mechanical performance of the overall composite. It is therefore important to characterize the mechanical integrity of this layer of fiberglass in order to quickly take stock of the overall state of the composite assembly.

The bending stress applied during the storage and transport of the rod made of composite materials also plays a role in the propagation of critical defects initiated in the composite core based on carbon fibers to the upper layer of glass fibers by virtue of the cohesive appearance between the two layers, and thus may also generate damage to the assembly. The same applies during high-voltage line mounting operations.

All of these parameters show the need to control the quality of these assemblies in terms of mechanical performance, both in production and also on their installation sites.

Among the conventional non-destructive testing means for such composite assemblies, several options known to the person skilled in the art have been envisaged (in particular by ultrasound, tomography, etc.). However, none has made it possible to respond to the challenges of a bi-composite assembly, nor to the needs of industrial scale and the high rates specific to the pultrusion manufacturing process.

In order to overcome the aforementioned disadvantages, the Applicant has developed a method for monitoring the quality of a composite multi-material assembly from the measurement of the breakdown voltage.

The use of the breakdown voltage measurement is known to a person skilled in the art in the field of overhead cables (1), (2), as well as in the wind turbine industry (3), (4). In particular, in the field of overhead cables, it is known to use the breakdown voltage in insulators to monitor the state of the insulation (1). In the wind turbine industry, for example, the breakdown voltage is used as a production strategy for protecting the blades from lightning (3). However, no mention is made of monitoring the mechanical quality of a bi-material composite assembly.

### DESCRIPTION OF THE INVENTION

Therefore, the applicant has developed a discriminant control method for a composite multi-material assembly comprising at least one internal layer made of a first, electrically conductive composite material and a second layer made of a second, electrically insulating composite material, the second layer covering the first internal layer, the method being characterized in that it comprises the following steps:
preparing the composite multi-material assembly by exposing a part of the internal layer, the part constituting a first electrode;
applying a second electrode to the surface of the second layer, one of the first and second electrodes being earthed,
discriminant monitoring by generating a current (which can be DC or AC) between the first and second electrodes by applying a threshold voltage U_{S} pre-defined by calibration so as to be characteristic of a lack of structural defects, the appearance of a breakdown at a voltage (called breakdown voltage) lower than said threshold voltage U_{S} being indicative of the presence of at least one structural defect in said composite assembly.

In the context of the present invention, the composite multi-material assembly is a monolithic composite material, manufactured in a single step, in which the second layer (or external layer) is cohesive to the internal layer, these two layers constituting structural layers in the composite multi-material assembly according to the invention. Such a composite multi-material assembly is said to be “cohesive.”

In the method according to the invention, discriminant monitoring is carried out in order to detect, or even to locate, a defect present in the second (external) layer made of insulating material and/or in the internal layer (made of an electrically conductive material) propagating under storage stress through the external layer.

The generating of current and the measurement of the breakdown voltage can in particular be carried out, in the context of the present invention, by an insulation tester. In order to be able to carry out the discriminant monitoring of the composite multi-material assembly and, if necessary, to detect any structural defects and to characterize same, it is necessary to carry out calibration beforehand. This is carried out for each assembly of given characteristics (thickness of the insulating layer, and dielectric properties of the constituent materials of the assembly) using different composite multi-material assemblies, some of which are known to be without defects, while one part comprises a layer made of insulating material having a known structural defect. On the basis of these known assemblies, a calibration of the discriminant monitoring method according to the invention described above is carried out, by noting the value of the breakdown voltage (as shown in example 1, as well as in FIG. 5):
for each assembly having a given critical structural defect, and
for each healthy composite assembly, i.e. lacking structural defects.

During the discriminant monitoring method, the measurement of a breakdown voltage makes it possible, thanks to the prior calibration, to identify the critical structural defect of the tested composite assembly either in the second layer (or exterior layer) alone, or in both layers (for example, cracks, impacts, high porosity or defects related to the manufacturing process).

As fibers that can be used in the first electrically conductive composite material, mention may in particular be made of metal fibers or carbon fibers, especially in the form of structural long fibers. In the context of the present invention, carbon fibers will preferably be used.

As fibers that can be used in the second electrically insulating composite material, mention may in particular be made of glass, basalt, boron, silica fibers, or thermoplastic fibers, in particular in the form of structural long fibers. In the context of the present invention, glass fibers will preferably be used.

According to a first advantageous embodiment of the method according to the invention, it may in particular be applied more particularly to a composite multi-material assembly comprising a tubular-shaped composite reinforcing element (or rod) intended to be used in an overhead electric cable, this assembly being obtained by steps of simultaneous stacking and firing of the internal layer and of the second layer, the internal layer being obtained by pultrusion from a bundle of carbon fibers and a polymer matrix impregnating the carbon fibers and binding them together, and the second layer being obtained during the same pultrusion operation from a bundle of glass fibers and said polymer matrix impregnating the glass fibers and binding them together. The assembly is cured or partially cured simultaneously to ensure cohesive continuity between the two structural layers (internal layer and second layer), facilitating the circulation of structural defects generated in one of the two layers toward the other layer.

The terms “steps of instantaneous stacking and firing” also means, by extension, “near-instantaneous”, that is slightly offset over time by a few seconds, and preferentially offset by a duration strictly less than 30 seconds.

The use of a polymer matrix of the same nature in the internal layer (impregnating the carbon fibers) and in the second layer (impregnating the glass fibers) promotes the propagation of the critical defects through all the layers of the assembly by virtue of a cohesive junction between the two structural layers (internal layer and second layer).

Furthermore, the fact that the polymer matrix impregnating the carbon fibers is polymerized during the same firing step and the polymer matrix (of the same nature) impregnating the glass fibers increases the propagation of the critical defects through all the layers of the assembly, this intimate bond between the layers being an essential element to the good mechanical characterization described in the present invention.

The first embodiment of the method according to the invention makes it possible to identify a defect in the rod in the case where the integrity of the second layer made of insulating material is compromised (defect or damage): this can be carried out directly on the rod at the end of production (according to a first alternative embodiment) or on-site, in particular when the rod is unwound (according to a second alternative embodiment), as detailed below.

Thus, according to a first alternative embodiment of this first advantageous embodiment, the step of discriminant monitoring of the composite multi-material assembly can be carried out on the production line of the tubular reinforcing element of tubular shape after the steps of stacking and firing the internal layer and second layer of the tubular-shaped composite reinforcing element and prior to a step of winding onto a rotating device (such as a reel) of the tubular-shaped composite reinforcing element thus obtained, the method comprising the following steps:
preparing one of the ends of the tubular-shaped composite reinforcing element by securing to the rotating device, then by exposing the internal layer at the end secured to the rotating device, the end constituting the first electrode which is earthed,
applying a second electrode to the surface of the second layer;
rotating the rotating device, for winding the tubular-shaped composite reinforcing element;
discriminant monitoring by generating a current between the first and second electrodes by applying the threshold voltage Us.

According to a second alternative embodiment of this first advantageous embodiment, the discriminant monitoring step can be carried out during the unwinding of the tubular-shaped composite reinforcing element wound on the rotating device. In this case, the method could take place as follows by:
preparing one of the ends of the tubular-shaped composite reinforcing element wound onto the rotating device by exposing the internal layer at the end, which constitutes the first electrode which is earthed,
applying a second electrode to the surface of the second layer;
unwinding the tubular-shaped composite reinforcing element;
discriminant monitoring by generating a current between the first and second electrodes by applying the threshold voltage Us.

According to a second advantageous embodiment of the method according to the invention, it may in particular be applied more particularly to a composite multi-material assembly comprising, in addition to the rod (that is, the tubular-shaped composite reinforcing element), at least one external layer at least partially covering the second layer of the composite assembly (or rod), this external layer being made of electrically conductive material, preferably metallic, and better still made of stranded aluminum. The rod is wound on a reel during production and can reach lengths on the order of 4000 m. It is then covered with a layer of electrically conductive material and in particular metallic (for example made of aluminum) to constitute an overhead cable of a high-voltage electrical transmission line with a composite core (in particular shown in FIG. 2).

The second layer of the rod based on glass fibers constitutes an insulator between the external layer (typically made of aluminum) and the internal layer of the rod based on carbon fibers, thus preventing any form of galvanic corrosion from one another. The second embodiment of the method according to the invention uses the insulating nature itself in order to characterize a defect of the composite multi-material assembly, which would be an indicator of the health of the cable.

Preferably, in such a composite multi-material assembly, this external layer may consist of a plurality of conductive strands made of aluminum of trapezoidal shape which are helically wound around the rod to form the overhead cable.

According to an alternative embodiment of this embodiment, the discriminant monitoring step can be carried out as follows:
preparation of the composite multi-material assembly by exposing one of its ends, that end constituting the first electrode which is earthed, while the external layer constitutes the second electrode;
the discriminant monitoring itself, by generating a current between the first and second electrodes by applying the threshold voltage Us.

Preferably, the method according to this alternative embodiment may further comprise an additional step of electrical reflectometry detection, to detect and locate a defect in the composite multi-material assembly, this additional step of electrical reflectometry detection being carried out either after the discriminant monitoring step, or during this discriminant monitoring step by generating a current between the first and second electrodes by coupling the breakdown voltage technology to the electrical reflectometry technology.

Dielectric reflectometry making it possible to quantify the propagation time of the electrical signal between the emission and/or reception source of the electrical signal and the breakdown point in at least one of the two electrodes. The propagation time, associated with the speed of propagation of the signal in the material of at least one of the two electrodes, makes it possible to precisely define the positioning of the breakdown of the insulating layer of composite material.

### BRIEF DESCRIPTION OF THE FIGURES

Further advantages and particularities of the present invention will become apparent from the following description, given as a non-limiting example and made with reference to the attached figures and examples serving to illustrate the mechanical performance of the reinforcement devices according to the present invention.

FIG. 1 is a schematic sectional representation of a facility implementing the method according to the invention in the case of a composite multi-material assembly consisting of a tubular-shaped composite reinforcing element which consists of an internal layer based on carbon fibers and a second layer based on glass fibers (or rod);

FIG. 2 is a schematic sectional representation of a facility implementing the method according to the invention in the case of an overhead cable consisting of a composite multi-material assembly comprising, in addition to the tubular-shaped composite reinforcing element identical to that shown in FIG. 1, an external layer made of stranded aluminum;

FIG. 3 is a schematic sectional representation of a facility implementing the method according to the invention on the production line of the composite multi-material assembly as shown according to FIG. 1 (rod), after the steps of stacking and firing the internal layer and the second layer of the tubular-shaped composite reinforcing element and prior to its winding on a reel;

FIG. 4 is a schematic sectional representation of a facility implementing the method according to the invention during the unwinding of the rod as shown in FIGS. 1 and 3 wound on the rotating device;

FIG. 5 is a schematic representation of a vertical drop well (dynamic impact bed) to perform impact tests on composite reinforcing elements as shown in FIG. 1: the skilled person will understand, on perusing FIG. 5, that any impact bed would make it possible to obtain the same result;

FIG. 6 comprises different sections obtained by X-ray-tomography of a composite reinforcing element as shown in FIG. 1, when the latter has a defect;

FIG. 7 comprises two photographs showing the electrical reflectometry analysis on composite reinforcing elements of tubular shape as shown in FIG. 1 during reflectometry tests: on the left photograph, the reinforcing element is free of defects, while on the right photograph, the reinforcing element has a structural defect in the glass-fiber-based second layer.

In the following description, identical, similar or analogous elements will be referred to by the same reference numbers.

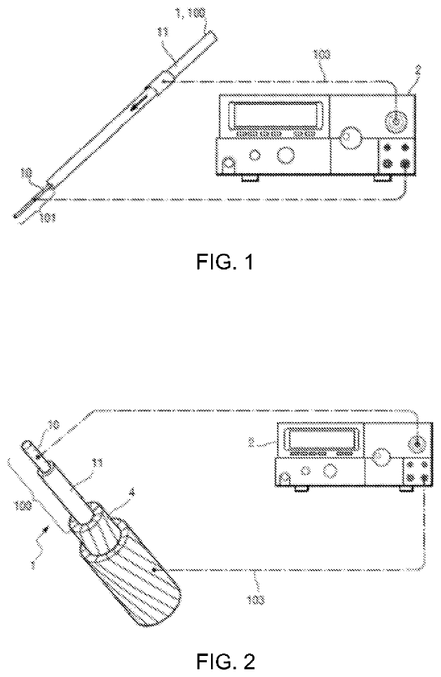

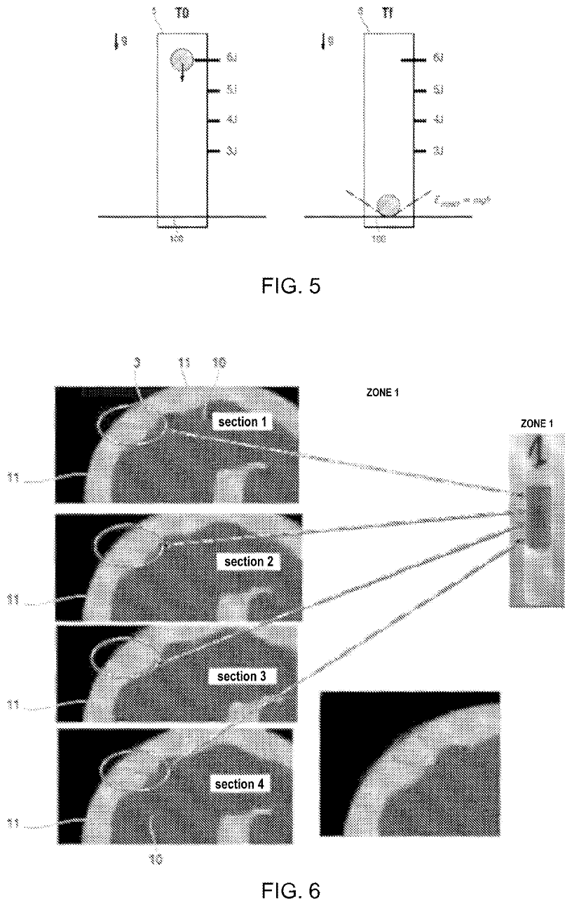

FIGS. 1 to 4 are described in greater detail in the detailed description of the figures, while FIGS. 5 to 7 are described in greater detail in the examples that follow, which illustrate the invention without limiting its scope.

### DETAILED DESCRIPTION OF THE FIGURES

FIG. 1 schematically shows a facility implementing the method according to the invention in the case of a composite multi-material assembly 1 consisting of a tubular-shaped composite reinforcing element 100 (or rod 100) which consists of an internal layer 10 based on carbon fibers and a second layer 11 based on glass fibers. This composite reinforcing element 100 is obtained by steps of stacking and firing the internal layer 10 and of the second layer: the internal layer 10 is previously obtained by pultrusion from a bundle of carbon fibers and a polymer matrix impregnating the carbon fibers and binding them to one another, and the second layer 11 is obtained during the same pultrusion operation from a bundle of glass fibers and the same polymer matrix that also impregnates the glass fibers by binding them to one another.

FIG. 1 in particular shows that a part 101 of the internal layer 10 is exposed, for example by polishing the second layer until reaching the internal layer 10 based on carbon fibers. This part 101 of the tubular reinforcing element of tubular shape 100 exposes the internal layer constituting a first electrode. A second electrode 103 is then arranged on the surface of the tubular reinforcing element of tubular shape 100, on the second layer 11 based on glass fibers, for example using a metal ring (in particular made of aluminum) encircling the layer 11 made of glass. An apparatus such as an insulation tester 2 is then connected to each of the electrodes 101, 103 (at least one of the two is earthed), then powered up to a threshold voltage Us, which is pre-defined by calibration to be characteristic of an absence of structural defects (see example 1 detailing how this calibration is carried out). The detection of a breakdown means the existence of a structural defect 3 in the second layer based on glass fibers 11. In this case, the composite multi-material assembly 1 must be deemed to be non-compliant and discarded.

FIG. 2 schematically shows the same facility as that shown in FIG. 1, implementing the method according to the invention in the case of a composite multi-material assembly 1 comprising, besides the tubular-shaped composite reinforcing element 100 of FIG. 1, two flexible external layers 4 made of stranded aluminum partially covering the reinforcing element 100 and thus forming an overhead electric cable. The second layer 11 based on glass fibers impregnated with a polymer matrix constitutes an electrical insulator between the external layer 4 made of aluminum and the internal layer 10 based on carbon fibers impregnated with the same polymer matrix, thus preventing any form of galvanic corrosion of one of the layers by the other.

The method according to the invention uses the electrical insulation properties of the internal layer 11 and the electrical conduction properties of the external layer 4 to detect and characterize, if necessary, the presence of a structural defect in the composite multi-material assembly 1 constituting the overhead cable.

In this particular case, when there is a breakdown, the location of the defect in the composite multi-material assembly 1 forming the cable is more complex than in the case of single rods 100 (shown in FIG. 1, 3 or 4) due to the large undervoltage surface area:

the assembly of the cable portion 1 is concerned and places the two electrodes 101, 103 face-to-face. Since a breakdown is therefore impossible to accurately locate, a complementary method for locating the fault by reflectometry is therefore advised, as shown in example 3.

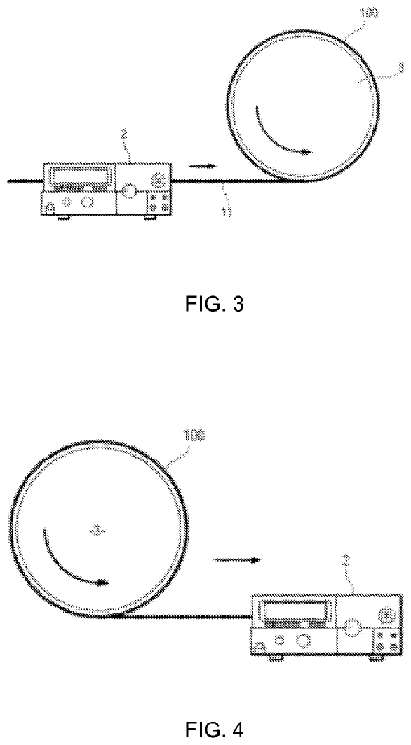

FIG. 3 shows a facility implementing the method according to the invention on the production line of the composite multi-material assembly as shown according to FIG. 1, that is, consisting solely of the composite reinforcing element 100 (or rod), prior to its winding onto a rotating device such as a reel 3. In this case, the discriminant monitoring method then takes place as follows:
as for the facilities for implementing the method according to the invention shown in FIGS. 1 and 2, the rod 100 is prepared at its end 101, by machining the second layer 11 until it reaches the internal layer 10 based on carbon fibers;
this end 101 of the rod 100 is then inserted into the insulation tester 2, then secured to the reel 3 in the location provided for this purpose: it constitutes the first electrode 101, which is earthed,
a second electrode 103 is applied to the surface of the rod 100 on the second layer 11 of the rod 100;
the insulation tester 2 is then connected to each of the electrodes 101, 103;
once the rotation of the reel 3 starts, the discriminant monitoring of the rod 100 is launched: the insulation tester 2 is powered on, and the voltage increases to the threshold voltage U_{S} (comprised between 5 kV and 40 kV, and preferentially between 8 kV and 20 KV, as illustrated in the examples below) which is pre-defined by calibration to be characteristic of a lack of structural defects (unless a breakdown is observed before reaching this voltage due to the actual presence of a structural defect in the rod 100);
a production operator observes the results of the discriminant monitoring on a monitoring screen in real time and can decide to intervene when a breakdown is observed (characterizing a defect present in the second layer 11 based on glass fibers): this intervention may consist either in a complete shutdown of the line of the facility, or in a local repair of the rod 100 without interrupting the facility.

FIG. 4 shows a facility implementing the method according to the invention on the production line of the overhead cable consisting of the composite multi-material assembly as shown according to FIG. 2, that is, consisting solely of the composite reinforcing element 100 (or rod 100) before the aluminum twisting step, during the unwinding of the rod 100 wound on the rotating device. In this case, the discriminant monitoring method then takes place as follows:
as for the facilities for implementing the method according to the invention shown in FIGS. 1 and 2, the rod 100 is prepared at its end 101, by machining the second layer 11 until it reaches the internal layer 10 based on carbon fibers;
this end 101 of the rod 100 is then inserted into the insulation tester 2, then secured to the reel 3 in the location provided for this purpose: it constitutes the first electrode 101, which is earthed,
a second electrode 103 is applied to the surface of the rod 100 on the second layer 11 of the rod 100;
the insulation tester 2 is then connected to each of the electrodes 101, 103;
once the rotation of the reel 3 starts, the discriminant monitoring of the rod 100 is launched: the insulation tester 2 is powered on, and the voltage increases to the threshold voltage U_{S} (comprised between 5 kV and 40 kV, and preferentially between 8 kV and 20 KV, as illustrated in the examples below) which is pre-defined by calibration to be characteristic of a lack of structural defects (unless a breakdown is observed before reaching this voltage due to the actual presence of a structural defect in the rod 100);
a production operator observes the results of the discriminant monitoring on a monitoring screen in real time and can decide to intervene when a breakdown is observed (characterizing a defect present in the second layer 11 based on glass fibers): this intervention may consist either in a complete shutdown of the facility, or in a local repair of the rod 100 without interrupting the production line.

### EXAMPLES

### Example 1: Calibration of the Discriminant Monitoring Method According to the Invention Using the Facility Shown in FIG. 1

In order to be able to carry out the discriminant monitoring of a composite multi-material assembly comprising an electrically conductive internal layer and a second electrically insulating layer and, where appropriate, to detect a possible structural defect in the second layer and to characterize it, it is appropriate to first perform a calibration in order to define the value of the threshold voltage Us, characteristic of a lack of any structural defect in the second layer. This calibration is carried out on the installation shown in FIG. 1, in which the device sold by the company RS Pro under the trade name ITT-2010 is used as an insulation tester 2.

The following samples are tested on this installation:
10 healthy rods 100 (i.e. not having any critical structural defect), of length 6 m+20 cm, and a plurality of rods 100 comprising known critical defects, of identical length to that of the healthy rods, comprising:
10 rods 100 having a defect of impregnation by the polymer matrix of the various fibers (carbon and/or glass) in the internal layer 10 and/or the second layer),
10 rods 100 having carbon jams, which has the effect of locally interrupting the alignment and integrity of these rods 100,
10 rods aged in a humid environment (for example samples that have spent at least 24 hours immersed in water at 90° C.),
10 rods 100 that have been subjected to different impacts in a vertical dynamic impact bed 5 (or impact drop tower) as shown in FIG. 5, which makes it possible to produce adjustable-energy linear shocks (various energy levels: between 3 Joules and 6 Joules), and finally 10 rods 100, the second layer 11 of which based on glass fibers was reduced by several tenths.

On the basis of these known assemblies, a calibration of the discriminant monitoring method according to the invention described above is carried out, by noting the value of the breakdown voltage (as shown in example 1 and in FIG. 5) for each rod having a given critical structural defect and for each healthy rod. The results of these tests are collated in table 1 below:

TABLE 1

| | Average voltage measured |
|---|---|
| Samples | (in V) just before breakdown |
| Rods subjected to wet aging | No breakdown observed |
| (24 h immersed in water at 90° C.) | |
| Rods impacted at 4 Joules | Breakdown observed from 4842 V |
| Rods impacted at 5 Joules | Breakdown observed from 4624 V |
| Rods impacted at 6 Joules | Breakdown observed from 2415 V |
| Rod with an insulation thickness | No breakdown observed |
| made of 0.4 mm thick fiberglass- | |
| reinforced composite | |
| Rod with an insulation thickness | No breakdown observed |
| made of 0.3 mm thick fiberglass- | |
| reinforced composite | |
| Rod with an insulation thickness | No breakdown observed |
| made of 0.2 mm thick fiberglass- | |
| reinforced composite | |
| Rod with an insulation thickness | No breakdown observed |
| made of 0.1 mm thick fiberglass- | |
| reinforced composite | |
| Healthy rods (of length 1.6 m) | No breakdown observed |

These calibration tests show that the rods having major defects break down at voltage levels below 6000 V.

### Example 2: Precalibration of the Discriminant Monitoring Method According to the Invention Using the Facility Shown in FIG. 3

Pre-calibration is carried out with a view to the in-line monitoring of a rod in accordance with the method according to the invention as shown in FIG. 3 and commented on in the corresponding descriptive section. This calibration is carried out on the installation shown in FIG. 3, in which the device sold by the company Zumba Electronic AG under the name DST28A is used as an insulation tester 2.

The samples tested are similar to those of example 1, but are similar to the calibration carried out in example 1. A voltage is applied with a ramp ranging from 0 to 28 kV and the breakdown voltage is measured for various types of rods with defects and various healthy rods. The results are collated in Table 2 below.

TABLE 2

| In-line testing carried | average voltage | |
|---|---|---|
| out on different types | measured (in V) just | |
| of rods | before breakdown | Comments |
| Rods subjected to wet | 14000 | 7 tests conducted |
| aging | | and 7 breakdowns |
| | | observed |
| Rods impacted at 3 Joules | 7000 | |
| Rods impacted at 4 Joules | 6000 | |
| Rods impacted at 5 Joules | 7000 | |
| Rods impacted at 6 Joules | 5500 | |
| Rods with dry fibers | 8000 | |
| (impregnation defects) | | |
| Rods with carbon jams | 3000 | |
| Healthy rods | 21000 | 3 tests carried out |

These calibration tests show that the rods having defects which also break down at voltage levels between 2000 V and 8000 V, whereas the healthy rods break down above 20000 V. Thus, for each composite multi-material assembly of characteristic data, the discriminant monitoring according to the method according to the invention may be carried out by applying the threshold voltage U_{S} at the end of which a threshold voltage value U_{S} is obtained, the latter therefore being in a range between 8000 V and 20000 V.

### Example 3: Reflectometry Tests

In the particular case of a composite assembly of the overhead cable type (as shown in FIG. 2, comprising in particular a rod and at least one external layer made of aluminum), when there is a breakdown, locating the defect in the composite multi-material assembly 1 forming the cable is more complex than in the case of single rods 100 (illustrated in FIG. 1, 3 or 4) due to the large surface area of the two electrodes which travels over almost the entire length of cable several hundred meters long, as indicated above. Since a breakdown is impossible to accurately locate, it is advised to carry out, in addition to the method according to the invention, tests for locating the fault by electrical reflectometry. During reflectometry tests, the electrical signal must be carried by two conductors. Any discontinuity in the analyzed product creates a reflection in the system, which can be localized by observing its transmission-reception delay. As for the breakdown voltage, electrical reflectometry tests rely on a physical principle of measuring the speed and propagation time of the electrical signal in a given material.

The purpose of the tests presented in this example is to test the feasibility of the reflectometry tests, by operating on specific samples of composite assemblies, consisting of rods 100 similar to those shown in FIG. 1, at the surface of which four copper wires (per rod 100) are inserted (thus playing the role of the external layer 4). The length of these samples (rod+copper wires) is 90 m. The carbon of the internal layer of the rods 100 and the copper in the external layer 4 therefore serve as a conductor to the electrical signal for reflectometry.

Once the samples are formed (rod assemblies and copper wires on the surface), the ends of the copper wires are removed from the assembly.

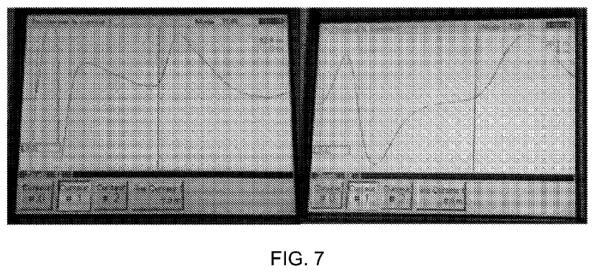

For these tests, the reflectometry tests are carried out using an EDTR (Electrical Time Domain Reflectometry) apparatus. The electrical wave speed is first calibrated between two copper wires by informing the apparatus of the propagation speed of the wave in the material without any shape or continuity defect (on the left in FIG. 7, where the only discontinuity of the signal observed on the screen by the operator is about 92.6 m at the outlet). It was then possible to successfully find the same length on the measurement between the other wires, and between the carbon core and a copper wire, thereby demonstrating the feasibility by electrical reflectometry detection between a metal conductor and the carbon core of our product. Finally, a copper wire at 30 m was intentionally broken, simulating a defect of one of the two conductors constituting the cable; the position of the defect was able to be accurately entered by the EDTR (on the right in FIG. 7, at 30.2 m) on the reflectometry apparatus, which identifies a large variation in the propagation speed of the wave at the electrical discontinuity generated in the conductive material.

The test therefore proved useful, and gives a precise defect location, as shown in FIG. 7. The photographs in FIG. 7, which indicate the linear position of the defect.

This method therefore is beneficial in the case of analyzing a cable at its installation site, where the two electrodes (stranded carbon and aluminum core) face one another over several hundred and/or thousands of meters: during a control of the quality of an overhead cable, a broken signal can be observed by a suitable reflectometer and allow the position of the defect in the rod to be located in return.

### Example 4: Tomography Analysis

Tomography analyses were carried out on a rod 100 having a defect and for which a breakdown was observed during the calibration of the discriminant monitoring carried out in example 1. FIG. 6 shows different sections taken on this rod, at different levels of the analyzed zone (central zone of the right-hand photograph). The fine substantially vertical black line that is observed at the surface of the analyzed central zone of the sample corresponds to the path of propagation of the electric arc of the breakdown. On transverse sections 1 to 4 (photographs from the left in FIG. 5), this is manifested by a defect present in the second layer 11 of the tested rod (white color and surrounded by an ellipse on each of the section photographs).

This analysis of a rod with a defect clearly shows that when a composite assembly, for example in the form of a rod 100 in the present case, has a defect that propagates in the assembly, the discriminant monitoring method according to the invention detects it.

### LIST OF REFERENCES

1—Ali Abedini-Livari, Mahdi Eshaghi-Maskouni, Mehdi Vakilian, Keyvan Firuzi. “Line Composite Insulators Condition Monitoring through Partial Discharge Measurement”; The 34th International Power System Conférence (PSC2019) 9-11 December, Niroo Research Institute, Tehran, Iran.
2—Enis Tuncer, sidor Sauers, D. Randy James, and Alvin R. Ellis. “Electrical Insulation Characteristics of Glass Fiber Reinforced Resins”; IEEE TRANSACTIONS ON APPLIED SUPERCONDUCTIVITY, VOL. 19, NO. 3, June 2009.
3—Sraren Find Madsen, J. Holboell, M. Henriksen, Flemming Mraller Larsen, Lars Bo Hansen, Kim Bertelsen. “Breakdown tests of Glass Fibre Reinforced Polymers (GFRP) as part of Improved Lightning Protection of Wind Turbine Blades”; Conference Record of the 2004 IEEE International Symposium on Electrical Insulation, Indianapolis, IN USA, 19-22 Sep. 2004.
4—S. F. Madsen, J. Holbøll and M. Henriksen Ørsted. “Direct relationship between breakdown strengthand tracking index of composites”; Conference Record of the 2006 IEEE International Symposium on Electrical Insulation.

1. A discriminant control method for a composite multi-material assembly comprising at least one internal layer made of a first, electrically conductive composite material and a second layer made of a second, electrically insulating composite material, said second layer covering said first internal layer, said method being characterized in that it comprises the following steps:
preparing said composite multi-material assembly by exposing a part of said internal layer, said part constituting a first electrode;
applying a second electrode to the surface of the second layer, one of the first and second electrodes being earthed,
discriminant monitoring by generating a current between the first and second electrodes by applying a threshold voltage pre-defined by calibration so as to be characteristic of a lack of structural defects, the appearance of a breakdown at a voltage lower than said threshold voltage being indicative of the presence of at least one structural defect in said composite assembly.

2. The method according to claim 1, wherein, in the composite multi-material assembly, the first electrically conductive material comprises carbon fibers.

3. The method according to claim 1, wherein, in the composite multi-material assembly, a second electrically insulating material comprises glass fibers.

4. The method according to claim 1, wherein, in the composite multi-material assembly, the first electrically conductive material comprises carbon fibers and a second electrically insulating material comprises glass fibers, wherein said composite multi-material assembly comprises a tubular-shaped composite reinforcing element intended to be used in an overhead electric cable, said composite multi-material assembly being obtained by simultaneous steps of stacking and firing said internal layer and said second layer, said internal layer being obtained by pultrusion from a bundle of carbon fibers and a polymer matrix impregnating said carbon fibers and binding them together, and said second layer being obtained during the same pultrusion operation from a bundle of glass fibers and said polymer matrix impregnating said glass fibers and binding them together.

5. The method according to claim 4, wherein the step of discriminant monitoring of said composite multi-material assembly is carried out on the production line of said tubular-shaped composite reinforcing element after the steps of stacking and firing said internal layer and said second layer of said tubular-shaped composite reinforcing element and prior to a step of winding onto a rotation device of said tubular-shaped composite reinforcing element thus obtained, said method comprising the following steps:
preparing one of the ends of said tubular-shaped composite reinforcing element by securing to said rotation device, then exposing said internal layer at said end, said end constituting the first electrode which is earthed;
applying a second electrode to the surface of the second layer;
rotating said rotating device, for winding the tubular-shaped composite reinforcing element;
discriminant monitoring by generating a current between the first and second electrodes by applying the threshold voltage.

6. The method according to claim 4, wherein the discriminant monitoring step is carried out during the unwinding of said tubular-shaped composite reinforcing element wound onto said rotating device, said method comprising the steps of:
preparing one of the ends of said tubular-shaped composite reinforcing element by securing to said rotation device, then exposing said internal layer at said end, said end constituting the first electrode which is earthed,
applying a second electrode to the surface of the second layer;
unwinding the tubular-shaped composite reinforcing element;
discriminant monitoring by generating a current between the first and second electrodes by applying the threshold voltage.

7. The method according to claim 4, wherein said composite multi-material assembly comprises, in addition to said tubular-shaped composite reinforcing element, at least one external layer at least partially covering said second layer, said external layer being made of an electricity-conducting material, preferably metal, and better still made of stranded aluminum.

8. The method according to claim 7, wherein the discriminant monitoring step comprises the following steps:
preparing said composite multi-material assembly by exposing an end of said composite multi-material assembly, said end constituting the first electrode which is earthed and the external layer constituting the second electrode;
discriminant monitoring by generating a current between the first and second electrodes by applying the threshold voltage.

9. The method according to claim 8, further comprising an additional step of electrical reflectometry detection, to detect and locate a defect in said composite multi-material assembly, this additional step of electrical reflectometry detection being carried out either after the discriminant monitoring step, or during said discriminant monitoring step by generating a current between the first and second electrodes by coupling the breakdown voltage technology to the electrical reflectometry technology.
